(19) United States
(12) Patent Application Publication
(10) Pub. No.: US 2009/0024900 A1
(43) Pub. Date: Jan. 22, 2009

(54) CYCLIC REDUNDANCY CHECKING IN LANE-BASED COMMUNICATIONS

(75) Inventors: Keith Iain Wilkinson, Fremont, CA (US); Roland Brill Dreier, Mountain View, CA (US); Hemant Vinchure, San Jose, CA (US)

Correspondence Address: SCHWEGMAN, LUNDBERG & WOESSNER, P.A., P.O. BOX 2938, MINNEAPOLIS, MN, 55402, US

(73) Assignee: Cisco Technology, Inc., San Jose, CA (US)

(21) Appl. No.: 11/779,730

(22) Filed: Jul. 18, 2007

(51) Int. Cl. H03M 13/15

(52) U.S. Cl. 714/758; 714/E11.032

(57) ABSTRACT

Various embodiments provide a system and method for cyclic redundancy checking in lane-based data communications. A particular embodiment provides a data stream receiver to receive an input data stream having a plurality of data lanes, and a lane-based CRC generator to generate a set of CRC values, each CRC value of the set of CRC values corresponding to a different data lane of the plurality of data lanes; and generate an aggregated CRC value from the set of CRC values.

### TECHNICAL FIELD

The disclosed subject matter relates to the field of computer network communications, and more particularly to lane-based communications.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to the software and data as described below and in the drawings that form a part of this document: Copyright 2006 Cisco Systems, Inc. All Rights Reserved.

### BACKGROUND

Serial data communication protocols normally provide check sequences for the transmitted data. This check sequence is verified by the receiver to ensure the lack of data corruption. The normal check sequence is a Cyclic Redundancy Check (CRC), which is based on the generation of some pre-defined polynomial. Standard polynomials are CRC-16, CCITT-16, CRC-32, etc. As an example CRC-32 is employed by Ethernet, Fibre Channel, Infiniband etc. and provides a 32 bit checksum of a data packet that is an integer number of 32 bit quantities in length. There are many ways to verify/generate the checksum. These include a LFSR (Linear Feedback Shift Register) with the data being clocked in one bit at a time. It is simple to establish the value of the shift register based on its original contents and the number of data bits clocked in. The final value of any bit in the LFSR is a series of XOR terms based on some LFSR bits and some data bits. The number of terms increases as the number of data bits increases.

Software implementations of the CRC algorithm tend to operate on the byte or word level rather than the bit level (bit operations being computationally-intensive for software). The conventional approach in hardware is to attempt the CRC calculation at the data path width (i.e. 32/64/128 bits etc.) This is common practice. With higher data rates, there has been the evolution to lane based or striped serial communications. So, rather than having a single serial data stream at 10 Gbits/sec, one can employ, for example, four data streams each of 2.5 Gbits/sec. This lane-based data communication technique is now common for PCI-express, Ethernet (XAUI) and Infiniband. The striping is typically partitioned at the octet level such that in a four lane environment, lane 0 will provide the lane for octets 0, 4, 8, 12 . . . ; lane 1 will provide the lane for octets 1, 5, 9, 13; etc. PCI express supports 1/2/4/8/16 and 32 lane configurations, Ethernet (XAUI) is four lanes and Infiniband supports 1/4/8 and 12 lane options.

Thus, a system and method for cyclic redundancy checking in lane-based data communications is needed.

### BRIEF DESCRIPTION OF THE DRAWINGS

FIG. 1 illustrates an architecture of a particular embodiment.

FIG. 2 is a flowchart illustrating an example embodiment of the lane-based CRC processor.

FIG. 3 illustrates an example computer system in which the features of an example embodiment may be implemented.

### DETAILED DESCRIPTION

In the following detailed description, reference is made to the accompanying drawings that form a part hereof, and in which are shown by way of illustration, specific embodiments in which the disclosed subject matter can be practiced. It is understood that other embodiments may be utilized and structural changes may be made without departing from the scope of the disclosed subject matter.

Existing data communications systems, such as PCI (Peripheral Component Interconnect) busses as described in the “PCI Local Bus Specification, Revision 2.1” set forth by the PCI Special Interest Group (SIG) on Jun. 1, 1995, may be utilized to deliver message data to and from I/O devices, namely storage subsystems and network devices via the data network. The PCI Extended (PCI-X) and PCI Express networking technology has also been developed. PCI Express is a new third-generation input/output (I/O) standard allowing enhanced Ethernet network performance beyond that of the older PCI and PCI-X desktop and server networking solutions. The higher performance of PCI Express derives from its faster, serial-bus architecture, which provides dedicated bi-directional I/O with 2.5 GHz clocking, versus the slower 133MHz parallel bus of PCI-X. PCI Express technology is described in a white paper entitled, “PCI Express Ethernet Networking”, published by Intel Corp. and dated September, 2005. Lane-based data communication techniques are now common for PCI-express and Ethernet (XAUI).

Other conventional data network architectures include InfiniBand™ and its predecessor, Next Generation I/O (NGIO) which have been developed by Intel Corp. and other companies to provide a standards-based I/O platform that uses a switched network and separate I/O channels instead of a shared memory-mapped bus architecture for reliable data transfers between end-nodes in a data network, as set forth in the “Next Generation Input/Output (NGIO) Specification,” NGIO Forum on Jul. 20, 1999 and the “InfiniBand™ Architecture Specification,” (IB network) the InfiniBand™ Trade Association on Oct. 24, 2000. Using NGIO/InfiniBand™, a host system may communicate with one or more remote systems using a Virtual Interface (VI) architecture in compliance with the “Virtual Interface (VI) Architecture Specification, Version 1.0,” as set forth by Compaq Corp., Intel Corp., and Microsoft Corp., on Dec. 16, 1997. NGIO/InfiniBand™ and VI hardware and software may often be used to support data transfers between an originating host network node and a destination target network node over one or more designated channels. Lane-based data communication techniques are now common for Infiniband systems.

A cyclic redundancy check (CRC) is a type of hash function, which is used to produce a small, fixed-size checksum of a larger block of data, such as a packet of network traffic or a computer file. The checksum is used to detect errors after transmission or storage. A CRC is computed and appended before transmission or storage, and verified afterwards by the recipient to confirm that no changes occurred in transit. CRC's are popular because they are simple to implement in binary hardware, are easy to analyze mathematically, and are particularly good at detecting common errors caused by noise in transmission channels. CRC algorithms which operate on 32-bit input (i.e. CRC32) are well known in the art.

As described further below, according to various example embodiments of the disclosed subject matter described herein, there is provided a system and method for cyclic redundancy checking (CRC) in lane-based data communications. In various embodiments, a system and method permits CRC calculations for lane-based communications to be performed at the lane level (i.e. computed independently of other lanes) with a single summation of the CRC results from each lane performed once at the end of packet reception.

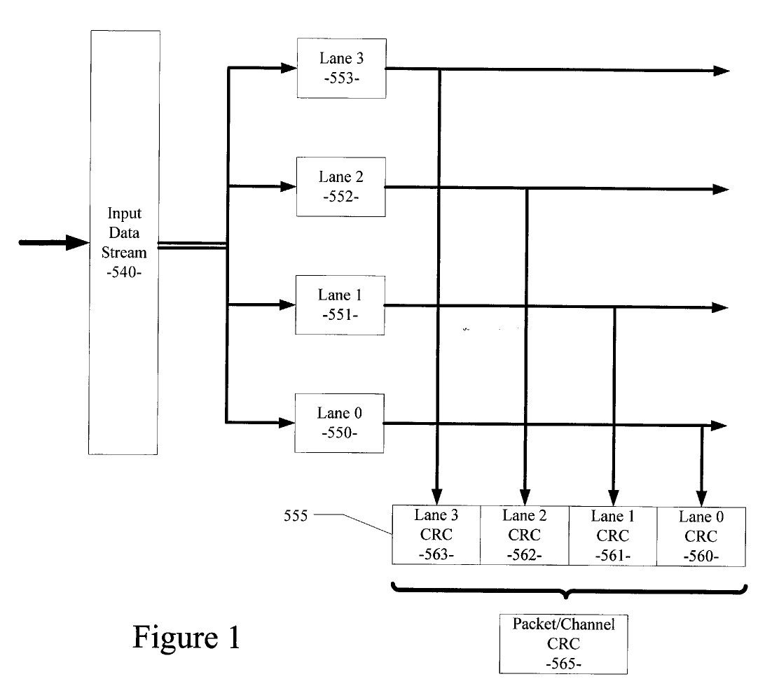

Referring to FIG. 1, an input data stream 540 is shown. The input data stream can be, in particular embodiments, either a 32 bit wide data stream or a 64 bit wide data stream. In either case, the input data stream 540 is split into a plurality of data lanes, each lane comprising a distinct portion of the input data stream 540. In particular embodiments, each lane can be an 8-bit byte for a 32 bit input data stream 540 or a 16-bit word for a 64 bit input data stream 540. In the particular embodiment shown in FIG. 1, four lanes 550, 551, 552, and 553 are shown each of these lanes can be an 8-bit byte for a 32 bit input data stream 540 or a 16-bit word for a 64 bit input data stream 540. The data for each of these lanes can be provided to processing units downstream as indicated by the straight horizontal arrows shown in FIG. 1. In parallel, lane-based CRC calculations can be performed on each lane as shown in FIG. 1. In particular, a lane 0 CRC value 560 can be calculated from the lane 0 data bits 550. A lane 1 CRC value 561 can be calculated from the lane 1 data bits 551. A lane 2 CRC value 562 can be calculated from the lane 2 data bits 552. A lane 3 CRC value 563 can be calculated from the lane 3 data bits 553. Finally, a single summation 565 of the CRC results from each lane (generally denoted an aggregated CRC value) can be generated once at the end of the reception of a data packet or channel reception from the input data stream 540.

In a first example embodiment, an input data width of 32 bits provides four (4) lanes of data with one byte (8 bits) of data corresponding to each of the four lanes. A CRC32 calculation can be used for each lane (byte) of the input data as described below.

In this first example embodiment, the following four CRC32 calculations can be used in parallel for 32 bit wide input data. Each CRC32 calculation works on an 8-bit byte N (lane) in the 32 bit input. (N=0,1,2,3).
crc32_xors_{—}4×_lane0—XOR equations for CRC32 calculation from byte lane 0
crc32_xors_{—}4×_lane1—XOR equations for CRC32 calculation from byte lane 1
crc32_xors_{—}4×_lane2—XOR equations for CRC32 calculation from byte lane 2
crc32_xors_{—}4×_lane3—XOR equations for CRC32 calculation from byte lane 3

A specific implementation of the above calculations is provided in Appendix A. It will be apparent to those of ordinary skill in the art that an equivalent process can be implemented in a different programming or scripting language.

In a second example embodiment, an input data width of 64 bits provides four (4) lanes of data with one word (16 bits) of data corresponding to each of the four lanes. A CRC32 calculation can be used for each lane (word) of the input data as described below.

In this second example embodiment, the following four CRC32 calculations can be used in parallel for 64 bit wide input data. Each CRC32 calculation works on a 16-bit word N (lane) in the 64 bit input. (N=0,1,2,3).
crc32_xors_{—}4×_word0—XOR equations for CRC32 calculation from word lane 0
crc32_xors_{—}4×_word1—XOR equations for CRC32 calculation from word lane 1
crc32_xors_{—}4×_word2—XOR equations for CRC32 calculation from word lane 2
crc32_xors_{—}4×_word3—XOR equations for CRC32 calculation from word lane 3

A specific implementation of the above calculations is provided in Appendix B. It will be apparent to those of ordinary skill in the art that an equivalent process can be implemented in a different programming or scripting language.

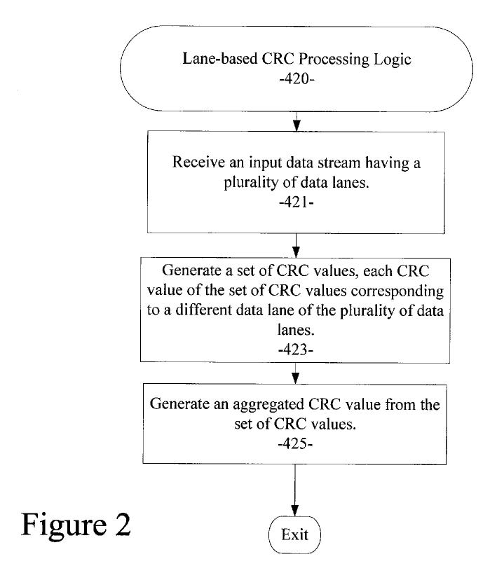

FIG. 2 is a flowchart illustrating an example embodiment of the lane-based CRC processor. As shown in processing block 421, the lane-based CRC processor receives an input data stream having a plurality of data lanes. In processing block 423, the lane-based CRC processor generates a set of CRC values, each CRC value of the set of CRC values corresponding to a different data lane of the plurality of data lanes. In processing block 425, the lane-based CRC processor generates an aggregated CRC value from the set of CRC values.

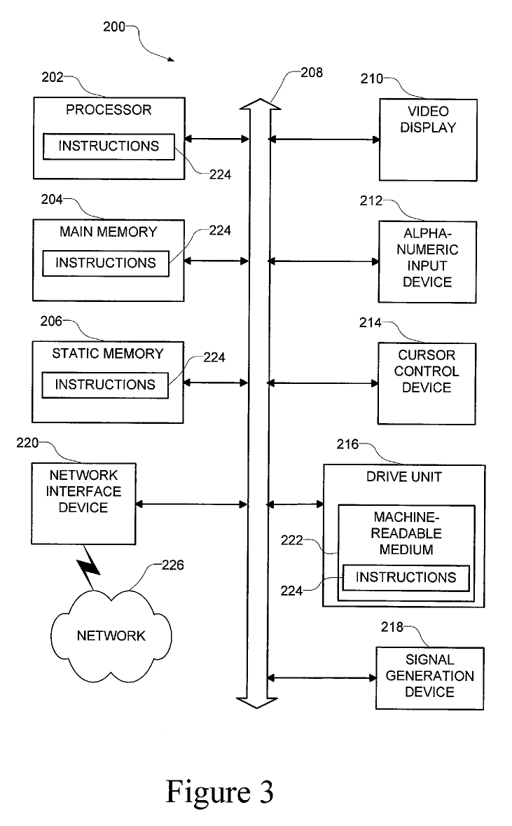

FIG. 3 shows a diagrammatic representation of machine in the example form of a computer system 200 within which a set of instructions, for causing the machine to perform any one or more of the methodologies discussed herein, may be executed. In alternative embodiments, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 200 includes a processor 202 (e.g., a central processing unit (CPU), a graphics processing unit (GPU) or both), a main memory 204 and a static memory 206, which communicate with each other via a bus 208. The computer system 200 may further include a video display unit 210 (e.g., a liquid crystal display (LCD) or a cathode ray tube (CRT)). The computer system 200 also includes an alphanumeric input device 212 (e.g., a keyboard), a user interface (UI) navigation device 214 (e.g., a mouse), a disk drive unit 216, a signal generation device 218 (e.g., a speaker) and a network interface device 220.

The disk drive unit 216 includes a machine-readable medium 222 on which is stored one or more sets of instructions and data structures (e.g., software 224) embodying or utilized by any one or more of the methodologies or functions described herein. The software 224 may also reside, completely or at least partially, within the main memory 204 and/or within the processor 202 during execution thereof by the computer system 200, the main memory 204 and the processor 202 also constituting machine-readable media.

The software 224 may further be transmitted or received over a network 226 via the network interface device 220 utilizing any one of a number of well-known transfer protocols (e.g., HTTP).

While the machine-readable medium 222 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present invention, or that is capable of storing, encoding or carrying data structures utilized by or associated with such a set of instructions. The term “machine-readable medium” shall accordingly be taken to include, but not be limited to, solid-state memories, optical and magnetic media, and carrier wave signals.

Although an embodiment of the present invention has been described with reference to specific example embodiments, it will be evident that various modifications and changes may be made to these embodiments without departing from the broader spirit and scope of the invention. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

Thus, as described above, a system and method for cyclic redundancy checking in lane-based data communications is disclosed. Although the disclosed subject matter has been described with reference to several example embodiments, it may be understood that the words that have been used are words of description and illustration, rather than words of limitation. Changes may be made within the purview of the appended claims, as presently stated and as amended, without departing from the scope and spirit of the disclosed subject matter in all its aspects. Although the disclosed subject matter has been described with reference to particular means, materials, and embodiments, the disclosed subject matter is not intended to be limited to the particulars disclosed; rather, the subject matter extends to all functionally equivalent structures, methods, and uses such as are within the scope of the appended claims.

We claim:

1. A method comprising:
receiving an input data stream having a plurality of data lanes;
generating a set of CRC values, each CRC value of the set of CRC values corresponding to a different data lane of the plurality of data lanes; and
generating an aggregated CRC value from the set of CRC values.

2. The method as claimed in claim 1 wherein the input data stream is 32 bits wide.

3. The method as claimed in claim 1 wherein the input data stream is 64 bits wide.

4. The method as claimed in claim 1 wherein each data lane of the plurality of data lanes is 8 bits wide.

5. The method as claimed in claim 1 wherein each data lane of the plurality of data lanes is 16 bits wide.

6. An apparatus comprising:
means for receiving an input data stream having a plurality of data lanes;
means for generating a set of CRC values, each CRC value of the set of CRC values corresponding to a different data lane of the plurality of data lanes; and
means for generating an aggregated CRC value from the set of CRC values.

7. The apparatus as claimed in claim 6 wherein the input data stream is 32 bits wide.

8. The apparatus as claimed in claim 6 wherein the input data stream is 64 bits wide.

9. The apparatus as claimed in claim 6 wherein each data lane of the plurality of data lanes is 8 bits wide.

10. The apparatus as claimed in claim 6 wherein each data lane of the plurality of data lanes is 16 bits wide.

11. A lane-based CRC processor comprising:
an data stream receiver to receive a input data stream having a plurality of data lanes; and
a lane-based CRC generator to generate a set of CRC values, each CRC value of the set of CRC values corresponding to a different data lane of the plurality of data lanes; and generate an aggregated CRC value from the set of CRC values.

12. The lane-based CRC processor as claimed in claim 11 wherein the input data stream is 32 bits wide.

13. The lane-based CRC processor as claimed in claim 11 wherein the input data stream is 64 bits wide.

14. The lane-based CRC processor as claimed in claim 11 wherein each data lane of the plurality of data lanes is 8 bits wide.

15. The lane-based CRC processor as claimed in claim 11 wherein each data lane of the plurality of data lanes is 16 bits wide.

16. A method comprising:
receiving an input data stream;
splitting the input data stream into a partitioned data stream having a plurality of data lanes;
generating a set of CRC values, each CRC value of the set of CRC values corresponding to a different data lane of the plurality of data lanes; and
generating an aggregated CRC value from the set of CRC values, the aggregated CRC value being associated with the partitioned data stream.

17. The method as claimed in claim 16 wherein the input data stream is 32 bits wide.

18. The method as claimed in claim 16 wherein the input data stream is 64 bits wide.

19. The method as claimed in claim 16 wherein each data lane of the plurality of data lanes is 8 bits wide.

20. The method as claimed in claim 16 wherein each data lane of the plurality of data lanes is 16 bits wide.
